(19) United States
(12) Patent Application Publication
(10) Pub. No.: US 2026/0252507 A1
(43) Pub. Date: Aug. 27, 2026

(54) Column Redundancy Circuitry Systems and Methods

(71) Applicant: Arm Limited, Cambridge (GB)

(72) Inventors: Rahul Mathur, Austin, TX (US); Andy Wangkun Chen, Austin, TX (US); Yew Keong Chong, Austin, TX (US)

(21) Appl. No.: 19/062,272

(22) Filed: Feb. 25, 2025

(51) Int. Cl. G06F 13/20

(52) U.S. Cl. CPC G06F 13/20; G06F 2213/40

(57) ABSTRACT

A circuit for column redundancy includes: one or more memory sub-arrays comprising: a plurality of bitcell columns; and a redundant input-output (I/O) circuitry comprising at least four redundant bitcell columns, where the circuit is configured to logically replace a subset of at least four bitcell columns of the plurality of bitcell columns with the at least four redundant bitcell columns. A method for column redundancy includes: detecting at least one faulty bitcell column in a memory sub-array; identifying a subset of at least four bitcell columns comprising the at least one faulty bitcell column; logically replacing the subset of at least four bitcell columns with at least four redundant bitcell columns from a redundant input-output (I/O) circuitry; and routing operational data through the at least four redundant bitcell columns.

### FIELD

The present disclosure is generally related to column redundancy systems, methods, and devices.

### DESCRIPTION OF RELATED ART

Column redundancy in memory circuits, particularly SRAM (Static Random-Access Memory) macros, addresses manufacturing defects that can render specific bitcell columns inoperative. These defects, such as shorted or open bitlines, are identified during manufacturing through a Built-In Self-Test (BIST) process. Redundant columns are then used to replace the faulty ones, ensuring the memory remains functional. While effective, current redundancy methods are highly inefficient in terms of area usage. In many designs, redundant Input/Output (I/O) “slices” are added in groups matching the full width of a primary I/O including eight columns, even when only one or two redundant columns are needed. Such an approach can simplify implementation but results in significant area penalties, particularly in high-density memory macros used in CPUs and other compact systems. This inefficiency is magnified when memory macros are replicated extensively, creating a critical need to reduce the area impact of column redundancy without sacrificing fault coverage or reliability. Accordingly, there is a pressing need for solutions that minimize area penalties in redundancy schemes while offering scalability and compatibility across diverse memory technologies.

### BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is an example diagram in accordance with various implementations described herein.

FIG. 2 is an example diagram in accordance with various implementations described herein.

FIG. 3 is an example table in accordance with various implementations described herein.

FIG. 4 is an operational method in accordance with various implementations described herein.

FIG. 5 is an operational method in accordance with various implementations described herein.

FIG. 6 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

Implementations of the present disclosure are described below with reference to the drawings. In the description, common features are designated by common reference numbers throughout the drawings.

In one implementation, the present disclosure describes a circuit for column redundancy. The circuit includes: one or more memory sub-arrays including a plurality of bitcell columns, and a redundant input-output (I/O) circuitry including at least four redundant bitcell columns. In addition, the circuit is configured to logically replace a subset of at least four bitcell columns of the plurality of bitcell columns with the at least four redundant bitcell columns.

In another implementation, the present disclosure describes a method for column redundancy. The method includes: 1) detecting at least one faulty bitcell column in a memory sub-array; 2) identifying a subset of at least four bitcell columns including the at least one faulty bitcell column; 3) logically replacing the subset of at least four bitcell columns with at least four redundant bitcell columns from a redundant input-output (I/O) circuitry; and 4) routing operational data through the at least four redundant bitcell columns.

In another implementation, the present disclosure describes a circuit for column redundancy. The circuit includes one or more I/O circuitries, each having: first and second redundancy input multiplexers configured to transmit data to a read multiplexer, and first and second redundancy output multiplexers configured to receive data from an input data latch. Also, the input and output redundancy multiplexers are configured to perform memory access operations through redundant bitcell columns.

To address the inefficiency in conventional column redundancy schemes and reduce area penalty, inventive aspects of the present invention introduce a more granular and efficient approach to redundancy management within memory macros (i.e., memory macro units). Instead of duplicating redundant I/O slices equivalent to the full width of the primary I/O (e.g., eight columns), inventive aspects reduce the number of redundant columns per I/O to four. This reduction is achieved by implementing redundancy multiplexer and control circuitry designed to selectively logically replace faulty columns in subsets of four bitcell columns. This novel approach minimizes area consumption while maintaining comprehensive functionality and fault coverage.

In addition, inventive aspects employ redundancy multiplexers strategically positioned within I/O of a memory macro. These redundancy multiplexers enable the dynamic logical replacement of faulty columns with redundant columns. On the input side, redundancy multiplexers are repositioned after the latch stage to optimize routing for write operations. On the output side, redundancy multiplexers are adjusted to facilitate seamless data flow during read operations. This configuration ensures efficient fault handling with minimal impact on the performance or power of the memory macro.

Furthermore, an additional fault column address (FCA) bit can be employed to identify faulty columns with greater precision. This FCA bit allows the system to target faults within subsets of four columns, rather than requiring redundant slices that match the entire I/O width. By enabling fault replacement at this granularity, inventive designs significantly reduce the area overhead traditionally associated with redundancy mechanisms. While initially designed for SRAM, the redundancy designs can be adapted for other memory technologies, such as MRAM and DRAM. In such adaptations, the redundancy logic and multiplexing architecture can be modified to accommodate the characteristics of these memory types. Moreover, such schemes can be expanded to handle larger column group sizes, such as 16 columns, by proportionally increasing the number of redundant columns.

Advantageously, by dynamically managing redundancy at a finer granularity, the invention provides a practical and efficient solution to the problem of area penalties in high-density memory macros. The disclosed schemes and techniques ensure fault tolerance and reliability while optimizing area efficiency, making the design particularly suitable for modern CPUs and other performance-critical applications where memory macros are replicated extensively.

Certain definitions have been provided herein for reference. A memory macro (e.g., memory macro unit, butterfly architecture) refers to a symmetric and interleaved arrangement of memory components, including bitcell arrays, word-line drivers, and input-output circuitries, within a memory macro. This architecture optimizes signal propagation, reduces area overhead, and enhances power distribution by leveraging balanced and mirrored layouts, commonly used in high-performance memory systems such as SRAM. A memory subarray in a memory macro is a smaller, organized section of the overall memory array that comprises a subset of bitcells, word lines, and bit lines, along with associated peripheral circuitry. Subarrays are used to partition the memory for efficient access, reduced latency, and optimized signal distribution, enabling scalable and high-performance memory architectures.

Input/Output (I/O) (e.g., I/O circuitry) in a memory macro refers to circuitry that facilitates data transfer between the memory sub-array and external components, where each I/O circuitry corresponds to a subset of eight bitcell columns (pitch-wide) of the sub-array, managing read and write operations efficiently. Redundant I/O in a memory macro refers to additional input/output circuitry comprising redundant bitcell columns and associated multiplexers, configured to replace faulty subsets of bitcell columns in the memory sub-array to ensure reliable operation and maintain data integrity. Redundancy shifting multiplexers are circuit elements configured to selectively route data between redundant bitcell columns and corresponding data paths in a memory sub-array, enabling logical replacement of faulty columns to maintain operational reliability.

Faulty Column Address (FCA) information is a multi-bit signal that identifies the location of faulty bitcell columns within a memory sub-array, enabling precise redundancy operations. FCA pin is the physical or logical interface that carries the FCA information to control circuitry or redundancy multiplexers for use in redundancy operations. Memory slice refers to a partitioned section of a memory macro, typically encompassing a subset of bitcell columns, associated word-line drivers, and I/O circuitries, organized to enable efficient data access and scalability within the memory architecture.

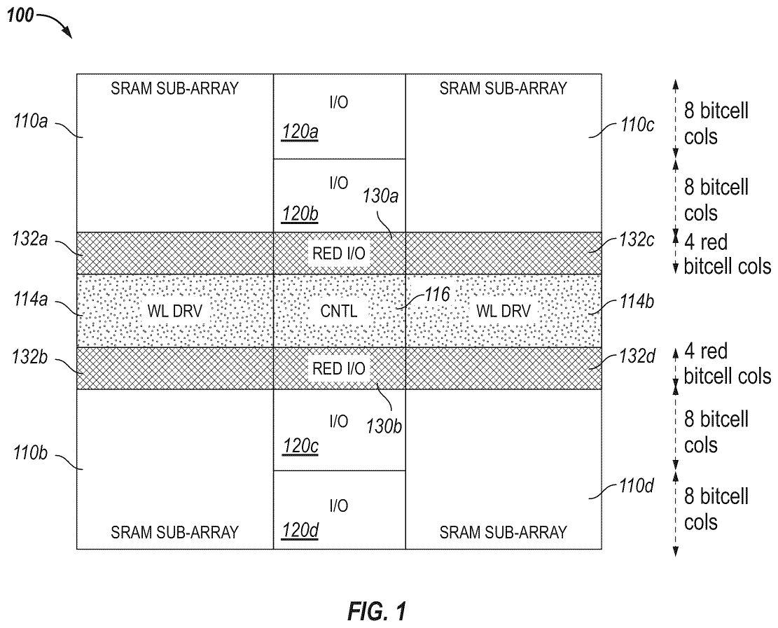

Referring to FIG. 1, a diagram of an example circuit 100 for column redundancy according to example implementations is shown. In certain implementations, the circuit 100 may be a memory macro (e.g., memory macro unit, “butterfly” architecture) having: one or more memory sub-arrays 110, word-line drivers (WL DRV) 114, control circuitry 116, one or more input/output circuitry (I/O) circuitries 120, and redundant I/O circuitry 130. As illustrated, each of the sub-arrays 110 (e.g., 110a-110d) includes a plurality of bitcell columns. In certain cases, the plurality of bitcell columns can be organized in sets of, for example, 8 columns per input/output circuitry (i.e., I/O) slice. As such, each I/O circuitry of the one or more I/O circuitries 120 can be coupled to (e.g., associated to, correspond to) a subset of eight bitcell columns pitch of the one or more sub-array 110. Moreover, as illustrated, the redundant I/O circuitry 130 includes a first set of at least four redundant bitcell columns. In various aspects, the circuit 100 is configured to logically replace (e.g., “logically “shift”) a subset of at least four bitcell columns of the plurality of bitcell columns with the same at least four redundant bitcell columns. Advantageously, redundancy can be allocated at the four-column level, rather than at the conventional eight-column level. In doing so, inventive aspects allow for more granular fault management while reducing the required area overhead.

Also, in FIG. 1, the word-line drivers (WL DRV) 114 (e.g., 114a-114b) can activate specific rows within the memory sub-arrays 110. As shown, in one example, the memory macro 100 integrates the redundant I/O circuitry 130a including two sets of four redundant bitcell columns 132a, 132c that are used as replacements for faulty columns identified during built-in self-test (BIST) operations. Similarly, the memory macro 100 integrates the redundant I/O circuitry 130b including two sets of four redundant bitcell columns 132 e.g., 132b, 132d that are also used as replacements for faulty columns identified during built-in self-test (BIST) operations.

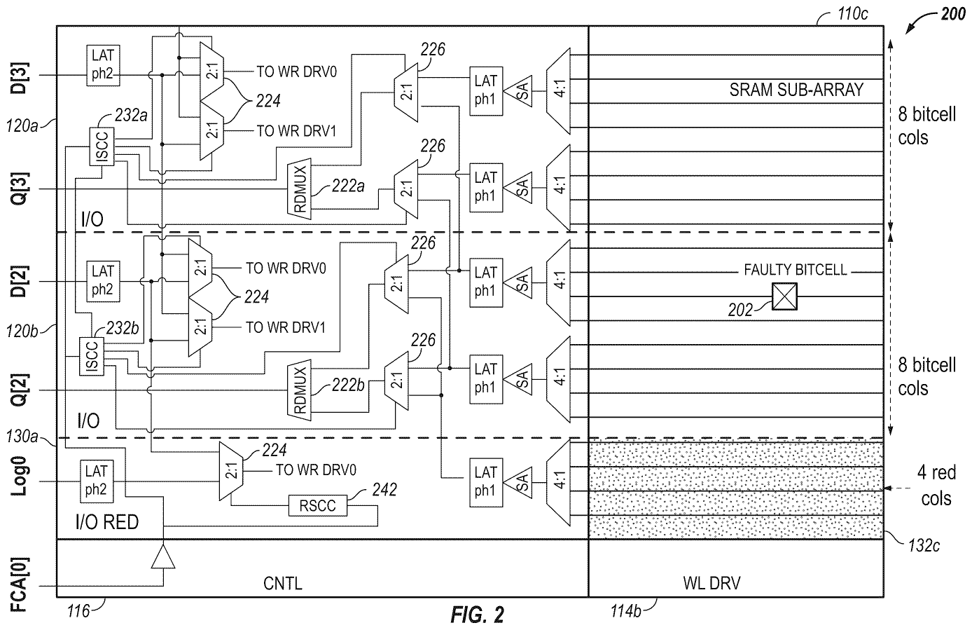

Referring to FIG. 2, a diagram of an example circuit 200 for column redundancy according to example implementations is shown. As illustrated, the circuit 200 may be a further detailed portion of the circuit 100. As shown in FIG. 2, each of the I/O circuitries 120a, 120b and the redundant I/O circuitry 130 include redundancy shifting multiplexers 140 (e.g., redundancy multiplexers, RDMUX) 140. In operation, each of the RDMUXs 140 is configured to selectively couple (e.g., “shift”) the at least four redundant bitcell columns to (for example, logically replace faulty bitcell columns of) the memory sub-array 10. In certain cases, the at least four redundant bitcell columns are selectively coupled to corresponding groups of at least four bitcell columns of the plurality of bitcell columns.

As illustrated, the control circuitry 116 is configured to receive fault column address (FCA) information (e.g., data received on faulty column address (FCA)); and dynamically enable a replacement of the subset of at least four bitcell columns (e.g., in the SRAM sub-array 110) with the at least four redundant bitcell columns 132 (e.g., 132c) based on the faulty column address (FCA) information (e.g., data received on, e.g., FCA[0]), where the subset of at least four bitcell columns includes one or more faulty bitcell columns (e.g., the bitcell column including faulty bitcell 202). In such implementations, the control circuitry 116 is configured to transmit a select signal based on the FCA pin; and select redundancy multiplexers (e.g., 224, 226) of the one or more I/O circuitries (e.g., 120a, 120b, etc.) using the FCA pin (e.g., FCA[0]).

In certain aspects, the redundant I/O circuitry (e.g., 130a) includes: an input data latch (e.g., D-latch, LAT ph2); and a redundancy multiplexer 224 (e.g., a D-mux) configured to receive data from the input data latch. In certain cases, the redundant I/O circuitry 130a includes a sole redundancy multiplexer 224 (e.g., just one D-mux). In some instances, each I/O circuitry of the one or more I/O circuitries (e.g., 130a, 130b, etc.) includes: an input data latch (e.g., D-latch); and first and second redundancy multiplexers 224 (e.g., for data input path for write operations; two D-muxes) configured to receive data from the (same one) input data latch (e.g., D-latch, LAT ph2). In certain instances, each I/O circuitry of the one or more I/O circuitries (e.g., 130a, 130b, etc.) includes: first and second redundancy multiplexers 226 (e.g., for read output path; two SAO-muxes), where: each of the first and second redundancy multiplexers 226 are configured to transmit data to a (single) read multiplexer 222 (e.g., 222a, 222b, etc. ; RDMUX). In certain aspects, each I/O circuitry of the one or more I/O circuitries includes: first and second output data latches (e.g., LAT ph1 per 4 cols.); and respective first and second redundancy multiplexers 226 (e.g., two SAO-muxes) configured to receive data from the first and second output data latches (e.g., LAT ph1).

In certain cases, as shown in FIG. 2, each of the one or more I/O circuitries 120 for column redundancy include: first and second redundancy input multiplexers 226 (e.g., for read output path; two SAO-muxes) configured to transmit data to a read multiplexer 222 (e.g., RDMUX); and first and second redundancy output multiplexers 224 (e.g., for data input path for write operations; two D-muxes) configured to receive data from the (same, one) input data latch (e.g., D-latch, LAT ph2), where the input and output redundancy multiplexers 224, 226 are configured to perform memory access operations through redundant bitcell columns (e.g., 132c).

In some implementations, as shown in FIG. 2, a redundant input/output (I/O) circuit portion includes: a redundant I/O 130 (e.g., I/O RED) and redundancy columns (e.g., 132c). As illustrated, the redundant I/O circuit 130 includes: a column multiplexer (e.g., 4:1 multiplexer for selection of a column); a sense amplifier (SA); a redundant multiplexer (e.g., 2:1 D-input Mux); and first and second latches (e.g., first and second LAT ph2). In one operation, the redundant I/O circuit portion is configured to shift (e.g., logically replace) data access operations to and from the at least four redundant columns (e.g., 132c).

According to various aspects, the control circuitry 116 along with ISCC 232 (as explained in following paragraphs) and RSCC 242 (as explained in following paragraphs) manages redundancy activation based on detected faults. The example control signals include: faulty column address (e.g., FCA[2]) pin to identify which columns within the sub-array 110 are faulty; redundancy control signal (e.g., column redundancy enable; (CRE)[2]) to enable or disable redundancy shifting; and column selection address (e.g., A[2]) to determine which 4-column group is being accessed.

In certain implementations, each I/O circuitry 120 (e.g., 232a, 232b, etc.) includes I/O shift control circuitry (ISCC) 232 (e.g., 232a, 232b, etc.). The ISCC 232 includes various logic elements (e.g., logic gates) to provide shifting control capability for each individual I/O circuitry 120. For instance, each ISCC 232 can receive a faulty column address signal (e.g., FCA[0]) from the control circuitry 116; and in turn, each ISCC 232 can generate two set of select signals (e.g., shift or nshift) since there are two redundancy multiplexers each for input (e.g., redundancy D-muxes 224) and output (e.g., redundancy SAO muxes 226). In some aspects, the select signals (e.g., shift or nshift; “shift-out” signals) are coupled as the select input signals for the redundancy multiplexers 224, 226. Moreover, an additional shift-out signal is coupled as a “shift-in” signal of a next I/O circuitry (e.g., an adjacent I/O tile). Additionally, in some aspects, programmable selection signals can be coupled to various FCA[1−n] or negated FCA[1−n] based on a specified I/O count.

In various aspects, each redundant I/O circuitry 130 (e.g., 130a, etc.) includes redundant I/O shift control circuitry (RSCC) 242. In certain examples, the RSCC 242 includes various logic elements (e.g., logic elements) for enabling or disabling the redundancy control signal (e.g., CRE[2]). In various examples, the RSCC 242 provides comparison between the column selection address (e.g., A[2]) and the faulty column address (e.g., FCA[2]) to determine whether a “shift” or “no-shift” occurred. In certain examples, the inwclk (e.g., a negated write clock signal) is disabled in the case of CRE=1 and no shift only scenario, while the inwclk is enabled for the CRE=0 scenario as well as the CRE=1 and shift scenario.

Advantageously, based on the ISCC 232 and RSCC 242, granular dynamic column shifting capability may be achieved. For instance, if and when a fault is present, the CRE signal may be asserted, activating redundancy and ensuring that data is routed through a functional column. Accordingly, such inventive schemes and techniques significantly reduce area overhead by allowing shifting at the 4-column level, compared to conventional systems that shift at the 8-column level.

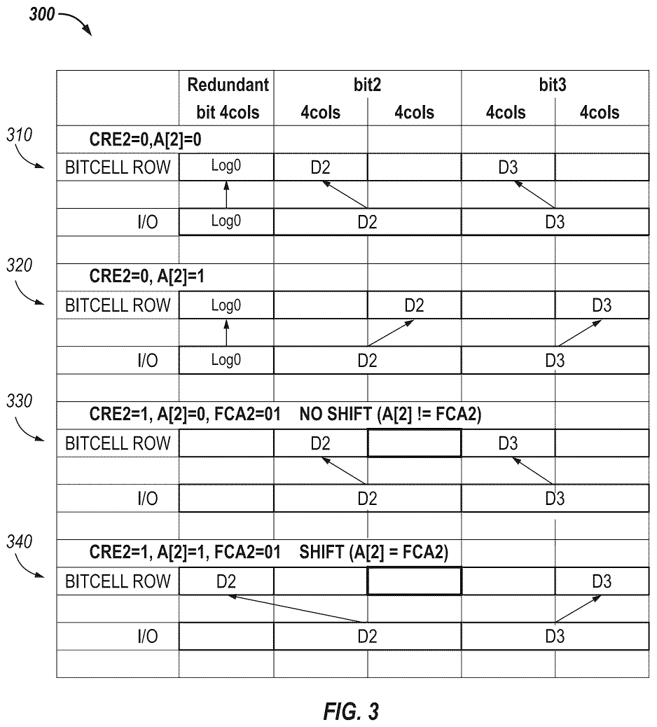

Referring to FIG. 3, a table 300 is shown according to example implementations. The table 300 illustrates the logical shift conditions with reference to the circuits 100 and 200 as shown with reference to FIGS. 1 and 2.

In a first example operation, as depicted in row 310, column redundancy (CR) is turned “off” (e.g., CRE2=0), indicating that no fault has been detected; and the column selection address (A2) is turned “off” as well (e.g., A2=0), indicating that the lower 4 columns of an 8 bitcell column grouping has been selected (e.g., to read from or write to). Hence, based on these control signals as shown, digital logic “0” (Log0) can be written to the four redundant bitcell columns (e.g., since the redundant bit is not applicable in this scenario, a “0” is written to it), and D2 and D3 signals can access the lower 4 columns (e.g., as shown as pointed to the “left” 4 cols for bit 2 and bit 3).

In a second example operation, as depicted in row 320, column redundancy (CR) is turned “off” (e.g., CRE[2]=0), indicating that no fault has been detected; and column selection address (A2) is turned “on” (e.g., A[2]=1), indicating that the upper 4 columns of an 8 bitcell column grouping has been selected (e.g., to read from or write to). Hence, based on these control signals as shown, digital logic “0” (Log0) can be written to the four redundant bitcell columns (e.g., since the redundant bit is not applicable in this scenario, a “0” is written to it), and D2 and D3 signals can access the upper 4 columns (e.g., as shown as pointed to the “right side” 4 cols for bit2 and bit3).

In a third example operation, as depicted in row 330, for instance, column redundancy (CR) is turned now “on” (e.g., CRE[2]=1), and column selection address (e.g., A[2]) is turned “off” (e.g., A[2]=0), indicating that the lower 4 columns of an 8 bitcell column grouping has been selected (e.g., to read from or write to). Moreover, according to inventive aspects, in this example, a multi-bit fault column address (e.g., FCA[2]) pin (e.g., 00, 01, 10, 11) can be utilized based on a Verilog model change. By doing so, the, e.g., multi-bit FCA[2] pin provides the capability to determine which of the four columns has a fault. For instance, each of the two-bit data: 00, 01, 10, 11 can be referenced to a different set of four columns that correspond to a set of four redundant bitcell columns. Advantageously, such inventive aspects provide for an increased granularity of information; that is, the information as to where the fault is, and not just if there is one. In this scenario, because FCA2=01, it is now known by the control circuitry 116 that the fault occurs in the second set of 4 bitcell columns (e.g., the upper 4 bitcell cols) of the 8 bitcell columns, whereas the column selection address A[2] as pointed by an example RDMUX is to the first set of 4 bitcell columns (e.g., the lower 4 bitcell cols). Hence, A[2]!=FCA[2]). Thus, inventive aspects can determine that since the data signal is not accessing the columns including the fault bitcell, no shift would be required (e.g., NO SHIFT). Accordingly, the data can continue to be, for example, read or written to the first set of 4 bitcell columns, and that there is no need to use the redundant columns. As may be appreciated, conventional designs, in such a scenario, previously would have performed a redundancy shift because the logic would not have the granularity of information available to know that there is not an error in the set of four columns where the data is to be read/written.

In a fourth example operation, as depicted in row 340, for instance, column redundancy (CR) is turned “on” (e.g., CRE2=1), while column selection address (e.g., A[2]) is also turned “on” (e.g., A[2]=1). In this scenario, as A[2]=1, an example RDMUX is pointing to the right side set as depicted (e.g., upper set) of 4 columns for access, which are the same columns where FCA[2] is showing that there is a fault (e.g., FCA[2]=01). Hence, because A[2] and FCA[2] match, the control circuitry 116 would initiate a logical shifting such that D2 would now access (e.g., for read/write operations) the four redundant columns instead (e.g., redundant bit 4 cols). Advantageously, such additional logic, as described herein, provides the capability to change the level of granular precision to four columns, instead of 8 columns.

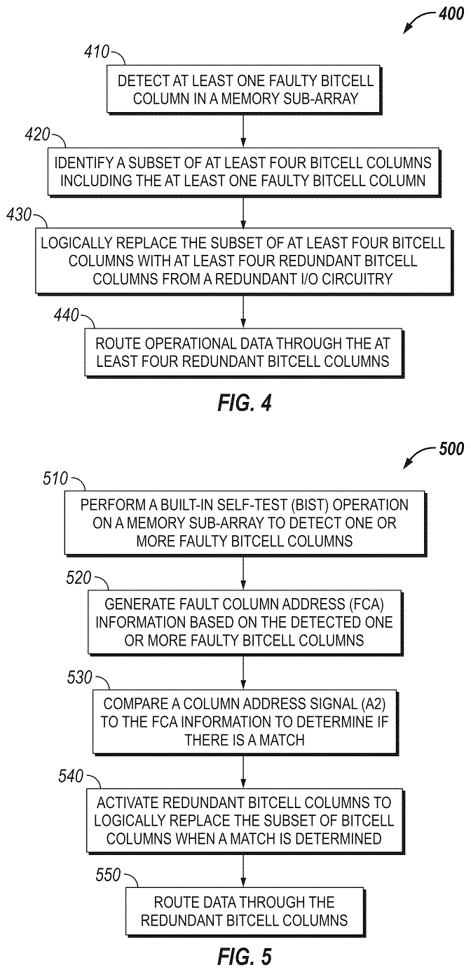

Referring to FIG. 4, a flowchart of an example operational method 400 (i.e., procedure) is shown. Advantageously, in various implementations, the method 400 describes the capability to manage column redundancy (e.g., in a memory macro). The method 400 may be implemented with reference to implementation as shown with reference to FIGS. 1-3. As would be appreciated, each step of the operational method is supported by control logic within the control circuitry 160 and/or the ISCC 232 and RSCC 242, which manage the selection and activation of the redundant columns. By enabling seamless replacement, this method significantly enhances the data integrity and fault tolerance of the memory macro without requiring external intervention.

At block 410, the example method 400 includes: detecting at least one faulty bitcell column in a memory sub-array. For instance, as described with reference to FIGS. 1-3, the at least one faulty bitcell column (e.g., column corresponding to faulty bitcell 202) can be detected in a memory sub-array (e.g., 110c).

At block 420, the example method 400 includes: identifying a subset of at least four bitcell columns comprising the at least one faulty bitcell column. For instance, as described with reference to FIGS. 1-3, a subset of at least four bitcell columns comprising the at least one faulty bitcell column can be identified (e.g., identifying a subset of four bitcell columns including faulty bitcell 202).

At block 430, the example method 400 includes: logically replacing the subset of at least four bitcell columns with at least four redundant bitcell columns from a redundant I/O circuitry (group). For instance, as described with reference to FIGS. 1-3, the subset of at least four bitcell columns (e.g., the subset of four bitcell columns including faulty bitcell 202) may be logically replaced with at least four redundant bitcell columns (e.g., 132c) from a redundant I/O circuitry (e.g., circuitry 130a in combination with 132c).

At block 440, the example method 400 includes: routing operational data through the at least four redundant bitcell columns. For instance, as described with reference to FIGS. 1-3, operational data may be routed through the at least four redundant bitcell columns (e.g., 132c).

In certain implementations, the example method 400 further includes: performing a Built-In Self-Test (BIST) operation on the memory sub-array to detect the at least one faulty bitcell column; and dynamically activating the at least four redundant bitcell columns for replacement.

In certain cases, identifying the subset of at least four bitcell columns includes: generating fault column address (FCA) information including a multi-bit value that identifies the subset of at least four bitcell columns including the at least one faulty bitcell column. For instance, in such cases, the fault column address (FCA) information includes a two-bit signal, where each bit corresponds to a fault status for one of the subsets of the at least four bitcell columns. In addition, in such cases, the method 400 further includes: comparing a column address signal (A2) to the fault column address (FCA) information to determine if the subset of at least four bitcell columns requires logical replacement. Moreover, in certain cases, the determinization if the subset of at least four bitcell columns requires replacement includes: identifying that replacement is not required when the column address signal (A2) does not match the fault column address (FCA) information; and identifying that replacement is required when the column address signal (A2) matches the fault column address (FCA) information.

In certain aspects, logically replacing the subset of at least four bitcell columns includes: disabling data paths associated with the identified subset of at least four bitcell columns; and activating data paths associated with the at least four redundant bitcell columns (e.g., 132c) in the redundant I/O circuitry (e.g., 132c in combination with 130a). In some implementations, routing the operational data through the at least four redundant bitcell columns includes: enabling redundancy multiplexers (e.g., 224, 226) to selectively couple the at least four redundant bitcell columns to the data paths (originally) associated with the subset of at least four bitcell columns having the at least one faulty bitcell column (e.g., the four bitcell columns including the faulty bitcell 202).

Referring to FIG. 5, a flowchart of an example operational method 500 (i.e., procedure) is shown. Advantageously, in various implementations, the method 500 describes the capability to more precisely determine and logically replace a faulty bit in a memory macro circuitry. The method 500 may be implemented with reference to implementation as shown with reference to FIGS. 1-3. As would be appreciated, each step of the operational method is supported by control logic within the control circuitry 160 and/or the ISCC 232 and RSCC 242, which manage the selection and activation of the redundant columns. By enabling seamless replacement, this method significantly enhances the data integrity and fault tolerance of the memory macro without requiring external intervention.

At block 510, the example method 500 includes: performing a Built-In Self-Test (BIST) operation on a memory sub-array to detect one or more faulty bitcell columns. For instance, with reference to FIGS. 1-3, a Built-In Self-Test (BIST) operation on a memory sub-array 110 can be performed to detect one or more faulty bitcell columns (e.g., a column including faulty bitcell 202).

At block 520, the example method 500 includes: generating fault column address (FCA) information based on the detected one or more faulty bitcell columns. For instance, with reference to FIGS. 1-3, fault column address (FCA) information can be generated based on the detected one or more faulty bitcell columns, where the FCA information (e.g., FCA2) includes a multi-bit value identifying a subset of the one or more faulty bitcell columns including a faulty bitcell (e.g., faulty bitcell 202).

At block 530, the example method 500 includes: comparing a column address signal (A2) to the FCA information to determine if there is a match. For instance, with reference to FIGS. 1-3, a column address signal (e.g., A2) can be compared to the FCA information (e.g., FCA2) to determine if there is a match, where the match indicates that a subset of bitcell columns addressed by the column address signal comprises the faulty bitcell.

At block 540, the example method 500 includes: activating redundant bitcell columns to logically replace the subset of bitcell columns when a match is determined. For instance, with reference to FIGS. 1-3, redundant bitcell columns can be activated to logically replace the subset of bitcell columns when a match is determined.

At block 550, the example method 500 includes: routing data through the redundant bitcell columns. For instance, with reference to FIGS. 1-3, data can be routed through the redundant bitcell columns (e.g., 132c) in place of the subset of bitcell columns containing the fault (e.g., faulty bitcell 202).

Advantageously, the disclosed column redundancy circuitry provides an efficient and scalable approach to memory fault tolerance. By introducing 4-column redundancy shifting instead of the traditional 8-column approach, schemes and techniques, as described herein, significantly reduce area overhead while maintaining robust functionality. The enhanced FCA-based redundancy logic ensures that data shifting occurs only when required, optimizing performance and memory reliability. Hence, inventive aspects are ideal for high-performance CPU memory macros and embedded systems.

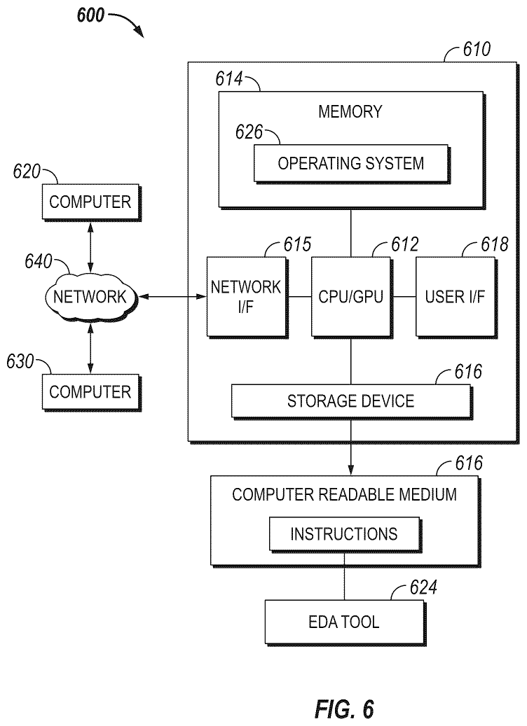

FIG. 6 illustrates example hardware components in the computer system 600 that may be used to facilitate and generate the inventive memory macro circuitry 100, 200. In certain implementations, the example computer system 600 (e.g., networked computer system and/or server) may include EDA tool 624 to execute software based on the procedure as described with reference to the methods as described herein. For example, FIG. 6 illustrates example hardware components in the computer system 600 that may be used to more precisely determine and logically replace a faulty bit in memory macro circuitry. In certain implementations, the EDA too 624 may be included as a feature of an existing compiler software program.

In certain implementations, an EDA (Electronic Design Automation) tool 624 plays a crucial role in the synthesis, simulation, verification, and optimization of the memory control logic to ensure the proper implementation of column redundancy features. For instance, the EDA tool 624 can facilitate: 1) Automated redundancy logic synthesis, enabling seamless integration of column redundancy mechanisms into the memory design; 2) Functional simulation, ensuring that the redundancy multiplexers correctly re-map faulty bitcell columns to redundant ones under various operating conditions; 3) Verification of timing and power characteristics, ensuring that redundancy operations do not introduce delays or excessive power consumption; and 4) Optimization of memory control logic, guaranteeing efficient handling of defect scenarios while maintaining high-speed operation.

In various applications, the EDA tool 624 is used to generate a fully functional memory macro incorporating novel I/O circuitry (including I/O control circuitry) 120, redundant I/O circuitry 130 (including redundant I/O circuitry), redundancy multiplexers 224, 226, and control circuitry 160. The EDA tool 624 ensures that all components interact correctly, providing robust column redundancy without requiring manual circuit modifications. The EDA tool 624 also automates post-layout validation, allowing designers to verify that the redundancy scheme functions as intended in both simulation and physical implementation stages.

By leveraging EDA-based automation, the described redundancy scheme can be efficiently integrated into modern semiconductor designs, improving yield and reliability while minimizing design complexity. This approach ensures that memory macros can dynamically adapt to detected defects, providing a scalable and efficient solution for high-performance memory architectures.

The procedures (e.g., 400, 500), for example, may be stored as program instructions as instructions 617 in the computer-readable medium of the storage device 616 (or alternatively, in memory 614) that may be executed by the computer 610, or networked computers 620, 630, other networked electronic devices (not shown), or a combination thereof. In certain implementations, each of the computers 610, 620, 630 may be any type of computer, computer system, or other programmable electronic device. Further, each of the computers 610, 620, 630 may be implemented using one or more networked computers, e.g., in a cluster or other distributed computing system.

In certain implementations, the system 600 may be used with semiconductor integrated circuit (IC) designs that contain all standard cells, all blocks, or a mixture of standard cells and blocks. In a particular example implementation, the system 600 may include in its database structures: a collection of cell libraries, one or more technology files, a plurality of cell library format files, a set of top design format files, one or more Open Artwork System Interchange Standard (OASIS/OASIS. MASK) files, and/or at least one EDIF file. The database of the system 600 may be stored in one or more of memory 614 or storage devices 616 of computer 610 or in networked computers 620, 630.

In one implementation, the computer 600 includes a central processing unit (CPU) 612 (or graphics processing unit (GPU) or neural processing unit (NPU) in certain implementations) having at least one hardware-based processor coupled to a memory 614. The memory 614 may represent random access memory (RAM) devices of main storage of the computer 610, supplemental levels of memory (e.g., cache memories, non-volatile or backup memories (e.g., programmable or flash memories)), read-only memories, or combinations thereof. In addition to the memory 614, the computer system 600 may include other memory located elsewhere in the computer 610, such as cache memory in the CPU 612, as well as any storage capacity used as a virtual memory (e.g., as stored on a storage device 616 or on another computer coupled to the computer 610).

The computer 610 may further be configured to communicate information externally. To interface with a user or operator (e.g., a circuit design engineer), the computer 610 may include a user interface (I/F) 618 incorporating one or more user input devices (e.g., a keyboard, a mouse, a touchpad, and/or a microphone, among others) and a display (e.g., a monitor, a liquid crystal display (LCD) panel, a light-emitting diode (LED) display panel, and/or a speaker, among others). In other examples, user input may be received via another computer or terminal. Furthermore, the computer 610 may include a network interface (I/F) 615, which may be coupled to one or more networks 640 (e.g., a wireless network) to enable communication of information with other computers and electronic devices. The computer 610 may include analog and/or digital interfaces between the CPU 612 and each of the components 614, 615, 616, and 618. Further, other non-limiting hardware environments may be used within the context of example implementations.

The computer 610 may operate under the control of an operating system 626 and may execute or otherwise rely upon various computer software applications, components, programs, objects, modules, data structures, etc. (such as the programs associated with the procedure 600 and related software). The operating system 626 may be stored in the memory 614. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States), i5/OS® (a registered trademark of IBM Corp.), and others as will occur to those of skill in the art. The operating system 626 in the example of FIG. 6 is shown in the memory 614, but components of the aforementioned software may also, or in addition, be stored at non-volatile memory (e.g., on storage device 616) and/or the non-volatile memory (not shown). Moreover, various applications, components, programs, objects, modules, etc. may also execute on one or more processors in another computer coupled to the computer 610 via the network 640 (e.g., in a distributed or client-server computing environment) where the processing to implement the functions of a computer program may be allocated to multiple computers 620, 630 over the network 640.

In example implementations, circuit-related diagrams have been provided in FIGS. 1-6, whose redundant description has not been duplicated in the related description of analogous circuit-related diagrams. It is expressly incorporated that the same diagrams with identical symbols and/or reference numerals are included in each of the embodiments based on its corresponding figure(s).

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the claimed invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the claimed invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit for column redundancy comprising:
one or more memory sub-arrays comprising: a plurality of bitcell columns; and
a redundant input-output (I/O) circuitry comprising at least four redundant bitcell columns, wherein the circuit is configured to logically replace a subset of at least four bitcell columns of the plurality of bitcell columns with the at least four redundant bitcell columns.

2. The circuit of claim 1, further comprising:
one or more input-output (I/O) circuitries, wherein each I/O circuitry is coupled to a subset of eight bitcell columns of the one or more sub-arrays.

3. The circuit of claim 2, wherein the circuit comprises:
redundancy multiplexers configured to selectively couple the at least four redundant bitcell columns to the memory sub-array.

4. The circuit of claim 3, wherein the at least four redundant bitcell columns are selectively coupled to corresponding groups of at least four bitcell columns of the plurality of bitcell columns.

5. The circuit of claim 1, further comprising:
control circuitry, wherein the control circuitry is configured to:
receive fault column address (FCA) information; and
enable a replacement of the subset of at least four bitcell columns with the at least four redundant bitcell columns based on the FCA information, wherein:
the subset of at least four bitcell columns comprises one or more faulty bitcell columns.

6. The circuit of claim 5, wherein the control circuitry is configured to:
transmit a select signal based on the faulty column address (FCA) pin; and
select redundancy multiplexers of the one or more I/O circuitries using the FCA pin.

7. The circuit of claim 1, wherein the redundant I/O circuitry comprises:
an input data latch; and
a redundancy multiplexer configured to receive data from the input data latch.

8. The circuit of claim 1, wherein the redundant I/O circuitry comprises:
a sole redundancy multiplexer.

9. The circuit of claim 1, wherein each I/O circuitry of the one or more I/O circuitries comprises:
an input data latch; and
first and second redundancy multiplexers configured to receive data from the input data latch.

10. The circuit of claim 1, wherein each I/O circuitry of the one or more I/O circuitries comprises:
first and second redundancy multiplexers, wherein:
each of the first and second redundancy multiplexers are configured to transmit data to a read multiplexer.

11. The circuit of claim 1, wherein each I/O circuitry of the one or more I/O circuitries comprises:
first and second output data latches; and
respective first and second redundancy multiplexers configured to receive data from the first and second output data latches.

12. A method for column redundancy comprising:
detecting at least one faulty bitcell column in a memory sub-array;
identifying a subset of at least four bitcell columns comprising the at least one faulty bitcell column;
logically replacing the subset of at least four bitcell columns with at least four redundant bitcell columns from a redundant input-output (I/O) circuitry; and
routing operational data through the at least four redundant bitcell columns.

13. The method of claim 12, further comprising:
performing a Built-In Self-Test (BIST) operation on the memory sub-array to detect the at least one faulty bitcell column; and
activating the at least four redundant bitcell columns for replacement.

14. The method of claim 12, wherein identifying the subset of at least four bitcell columns comprises:
generating fault column address information comprising a multi-bit value that identifies the subset of at least four bitcell columns comprising the at least one faulty bitcell column.

15. The method of claim 14, wherein:
the fault column address information comprises a two-bit signal, and
each bit of the two-bit signal corresponds to a fault status for one of the subsets of the at least four bitcell columns.

16. The method of claim 14, further comprising:
comparing a column address signal to the fault column address information to determine if the subset of at least four bitcell columns requires logical replacement.

17. The method of claim 16, wherein determining if the subset of at least four bitcell columns requires replacement comprises:
identifying that replacement is not required when the column address signal does not match the fault column address information; and
identifying that replacement is required when the column address signal matches the fault column address information.

18. The method of claim 12, wherein logically replacing the subset of at least four bitcell columns comprises:
disabling data paths associated with the identified subset of at least four bitcell columns; and
activating data paths associated with the at least four redundant bitcell columns in the redundant I/O circuitry group.

19. The method of claim 12, wherein routing the operational data through the at least four redundant bitcell columns comprises:
enabling redundancy multiplexers to selectively couple the at least four redundant bitcell columns to the data paths associated with the subset of at least four bitcell columns having the at least one faulty bitcell column.

20. A circuit for column redundancy comprising:
one or more I/O circuitries, each comprising:
first and second redundancy input multiplexers configured to transmit data to a read multiplexer; and
first and second redundancy output multiplexers configured to receive data from an input data latch, wherein the input and output redundancy multiplexers are configured to perform memory access operations through redundant bitcell columns.
